(19) United States
(12) Patent Application Publication
(10) Pub. No.: US 2026/0047092 A1
(43) Pub. Date: Feb. 12, 2026

(54) 3D FLASH MEMORY AND MANUFACTURING METHOD THEREOF

(71) Applicant: MACRONIX International Co., Ltd., Hsinchu (TW)

(72) Inventors: Wei-Chen Chen, Taoyuan City (TW); Hang-Ting Lue, Hsinchu County (TW)

(73) Assignee: MACRONIX International Co., Ltd., Hsinchu (TW)

(21) Appl. No.: 18/795,190

(22) Filed: Aug. 6, 2024

(51) Int. Cl. H10B 43/27

(52) U.S. Cl. CPC H10B 43/27

(57) ABSTRACT

Provided are a three-dimensional (3D) flash memory and a manufacturing method thereof. The 3D flash memory includes a stacked structure, an annular channel pillar, first and second source/drain pillars, and a charge storage structure. The stacked structure is disposed on a dielectric substrate and includes a plurality of gate layers and a plurality of insulation layers alternately stacked. The insulation layer includes an air gap. The channel pillar is disposed on the dielectric substrate and penetrates through the stacked structure. The first and second source/drain pillars are disposed on the dielectric substrate, located inside the channel pillar, and penetrate through the stacked structure. The first and second source/drain pillars are separated from each other, and each is connected to the channel pillar. The charge storage structure is disposed between each of the gate layers and the channel pillar.

### BACKGROUND

### Technical Field

The disclosure relates to a memory and a manufacturing method thereof, and more particularly, to a three-dimensional flash memory and a manufacturing method thereof.

### Description of Related Art

A flash memory has an advantage that stored data will not disappear even after a power outage, so it has become a memory widely used in personal computers and other electronic devices. A NOR flash memory is a three-dimensional flash memory commonly used in the industry, which may be applied in multi-dimensional flash memory arrays with a high integration degree and high area utilization, and has an advantage of fast operation speed.

### SUMMARY

The disclosure provides a three-dimensional flash memory and a manufacturing method thereof, in which an air gap is formed between adjacent gate layers in a stacking direction.

A three-dimensional flash memory in the disclosure includes a stacked structure, an annular channel pillar, a first source/drain pillar, a second source/drain pillar, and a charge storage structure. The stacked structure is disposed on a dielectric substrate and includes a plurality of gate layers and a plurality of insulation layers alternately stacked. Each of the insulation layers has an air gap. The channel pillar is disposed on the dielectric substrate and penetrates through the stacked structure. The first source/drain pillar and the second source/drain pillar are disposed on the dielectric substrate, located inside the channel pillar, and penetrate through the stacked structure. The first source/drain pillar and the second source/drain pillar are separated from each other, and each is connected to the channel pillar. The charge storage structure is disposed between each of the gate layers and the channel pillar.

In the embodiment of the three-dimensional flash memory of the disclosure, the air gap extends in an extension direction of the gate layer.

In the embodiment of the three-dimensional flash memory of the disclosure, a width of the air gap in the extension direction is greater than a thickness of the air gap in a stacking direction of the stacked structure.

In the embodiment of the three-dimensional flash memory of the disclosure, the charge storage structure includes a first silicon oxide layer, a second silicon oxide layer, and a silicon nitride layer located between the first silicon oxide layer and the second silicon oxide layer, and the first silicon oxide layer is in contact with the channel pillar.

In the embodiment of the three-dimensional flash memory of the disclosure, the insulation layer is in contact with the channel pillar, and the charge storage structure is located between the gate layer and the channel pillar and between the gate layer and the insulation layer.

In the embodiment of the three-dimensional flash memory of the disclosure, the first silicon oxide layer and the silicon nitride layer are located between the stacked structure and the channel pillar, and the second silicon oxide layer is located between the gate layer and the silicon nitride layer and between the gate layer and the insulation layer.

In the embodiment of the three-dimensional flash memory of the disclosure, the silicon nitride layer is continuous in a stacking direction of the stacked structure, so that the insulation layer is in contact with the silicon nitride layer.

In the embodiment of the three-dimensional flash memory of the disclosure, the silicon nitride layer is discontinuous in a stacking direction of the stacked structure, so that the insulation layer is in contact with the first silicon oxide layer.

In the embodiment of the three-dimensional flash memory of the disclosure, the charge storage structure is located between the channel pillar and the stacked structure, and the second silicon oxide layer is continuous in a stacking direction of the stacked structure, so that the insulation layer is in contact with the second silicon oxide layer.

In the embodiment of the three-dimensional flash memory of the disclosure, the charge storage structure is located between the channel pillar and the stacked structure, and the silicon nitride layer and the second silicon oxide layer are discontinuous in a stacking direction of the stacked structure, so that the insulation layer is in contact with the first silicon oxide layer.

In the embodiment of the three-dimensional flash memory of the disclosure, the gate layer includes a metal layer, and the three-dimensional flash memory further includes a high dielectric constant layer disposed between the gate layer and the charge storage structure.

In the embodiment of the three-dimensional flash memory of the disclosure, it further includes an insulation pillar disposed between the first source/drain pillar and the second source/drain pillar.

A manufacturing method of a three-dimensional flash memory in the disclosure includes the following steps. A stacked structure is formed on a dielectric substrate. The stacked structure includes a plurality of gate layers and a plurality of insulation layers alternately stacked, and each of the insulation layers has an air gap. An annular channel pillar is formed on the dielectric substrate. The channel pillar penetrates through the stacked structure. A first source/drain pillar and a second source/drain pillar are formed on the dielectric substrate. The first source/drain pillar and the second source/drain pillar are located inside the channel pillar and penetrate through the stacked structure, and the first source/drain pillar and the second source/drain pillar are separated from each other, and each is connected to the channel pillar. A charge storage structure is formed between each of the gate layers and the channel pillar.

In the embodiment of the manufacturing method of the three-dimensional flash memory of the disclosure, the air gap extends in an extension direction of the gate layer.

In the embodiment of the manufacturing method of the three-dimensional flash memory of the disclosure, a width of the air gap in the extension direction is greater than a thickness of the air gap in a stacking direction of the stacked structure.

In the embodiment of the manufacturing method of the three-dimensional flash memory of the disclosure, the charge storage structure includes a first silicon oxide layer, a second silicon oxide layer, and a silicon nitride layer located between the first silicon oxide layer and the second silicon oxide layer, and the first silicon oxide layer is in contact with the channel pillar.

In the embodiment of the manufacturing method of the three-dimensional flash memory of the disclosure, a method of forming the stacked structure and the charge storage structure includes the following steps. An initial stacked structure is formed on the dielectric substrate. The initial stacked structure includes a plurality of first insulation material layers and a plurality of sacrificial layers alternately stacked. The channel pillar, the first source/drain pillar, and the second source/drain pillar are formed in the initial stacked structure. The plurality of sacrificial layers are removed to form a plurality of first trenches. The charge storage structure is formed on surfaces of the first trenches. The gate layers are filled in the first trenches. The plurality of first insulation material layers are removed to form a plurality of second trenches. A second insulation material layer is conformally formed on a surface of the initial stacked structure, and end portions of the second trenches are sealed by the second insulation material layer, so as to form the insulation layers and the air gaps.

In the embodiment of the manufacturing method of the three-dimensional flash memory of the disclosure, a method of forming the stacked structure and the charge storage structure includes the following steps. An initial stacked structure is formed on the dielectric substrate. The initial stacked structure includes a plurality of sacrificial layers and a plurality of first insulation material layers alternately stacked. A channel hole is formed in the initial stacked structure. A sacrificial silicon oxide layer is formed on surfaces of the sacrificial layers exposed by the channel hole. The silicon nitride layer, the first silicon oxide layer, and the channel pillar are formed on a sidewall of the channel hole in sequence. The first source/drain pillar and the second source/drain pillar are formed in the channel hole. The plurality of sacrificial layers and the sacrificial silicon oxide layer are removed to form a plurality of first trenches. The second silicon oxide layer is formed on surfaces of the first trenches. The gate layers are filled in the first trenches. The plurality of first insulation material layers are removed to form a plurality of second trenches. A second insulation material layer is conformally formed on a surface of the initial stacked structure, and end portions of the second trenches are sealed by the second insulation material layer, so as to form the insulation layers and the air gaps.

In the embodiment of the manufacturing method of the three-dimensional flash memory of the disclosure, after the first insulation material layers are removed, the method further includes the following. The exposed silicon nitride layer is removed to expose the first silicon oxide layer.

In the embodiment of the manufacturing method of the three-dimensional flash memory of the disclosure, a method of forming the stacked structure and the charge storage structure includes the following steps. An initial stacked structure is formed on the dielectric substrate. The initial stacked structure includes a plurality of sacrificial layers and a plurality of first insulation material layers alternately stacked. A channel hole is formed in the initial stacked structure. The charge storage structure and the channel pillar are formed on a sidewall of the channel hole in sequence. The first source/drain pillar and the second source/drain pillar are formed in the channel hole. The plurality of sacrificial layers are removed to form a plurality of first trenches. The gate layers are filled in the first trenches. The plurality of first insulation material layers are removed to form a plurality of second trenches. A second insulation material layer is conformally formed on a surface of the initial stacked structure, and end portions of the second trenches are sealed by the second insulation material layer, so as to form the insulation layers and the air gaps.

In the embodiment of the manufacturing method of the three-dimensional flash memory of the disclosure, after the first insulation material layers are removed, the manufacturing method further includes the following. The exposed first silicon oxide layer is removed to expose the silicon nitride layer. The exposed silicon nitride layer is removed to expose the first silicon oxide layer.

In the embodiment of the manufacturing method of the three-dimensional flash memory of the disclosure, the gate layer includes a metal layer, and the manufacturing method further includes the following. A high dielectric constant layer is formed between the gate layer and the charge storage structure.

In the embodiment of the manufacturing method of the three-dimensional flash memory of the disclosure, the manufacturing method further includes the following. An insulation pillar is formed between the first source/drain pillar and the second source/drain pillar.

Based on the above, in the three-dimensional flash memory and the manufacturing method thereof of the disclosure, in the stacking direction of the stacked structure, the insulation layer located between the adjacent gate layers has the air gap. Therefore, the adjacent gate layers may have low capacitance values, thereby improving operation efficiency of the three-dimensional flash memory and avoiding increased interference between adjacent memory units.

### BRIEF DESCRIPTION OF THE DRAWINGS

FIGS. 1A to 1F are schematic cross-sectional views of a manufacturing process of a three-dimensional flash memory according to the first embodiment of the disclosure.

FIG. 1G is a schematic perspective view of the three-dimensional flash memory according to the first embodiment of the disclosure.

FIGS. 2A to 2F are schematic cross-sectional views of a manufacturing process of a three-dimensional flash memory according to the second embodiment of the disclosure.

FIGS. 3A to 3B are schematic cross-sectional views of a manufacturing process of a three-dimensional flash memory according to the third embodiment of the disclosure.

FIGS. 4A to 4D are schematic cross-sectional views of a manufacturing process of a three-dimensional flash memory according to the fourth embodiment of the disclosure.

FIGS. 5A to 5B are schematic cross-sectional views of a manufacturing process of a three-dimensional flash memory according to the fifth embodiment of the disclosure.

### DETAILED DESCRIPTION OF DISCLOSED EMBODIMENTS

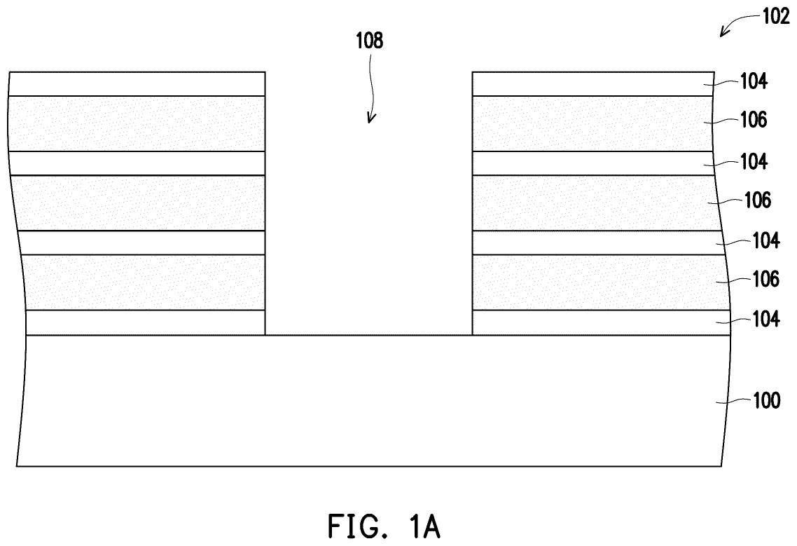

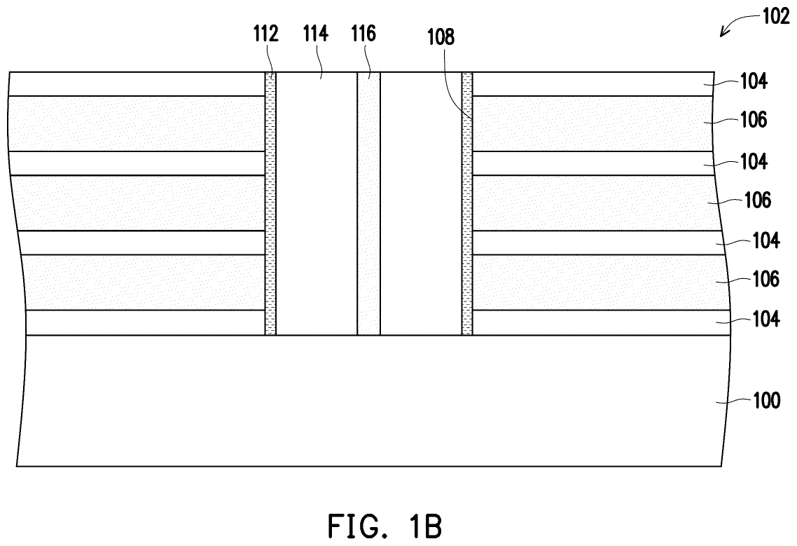

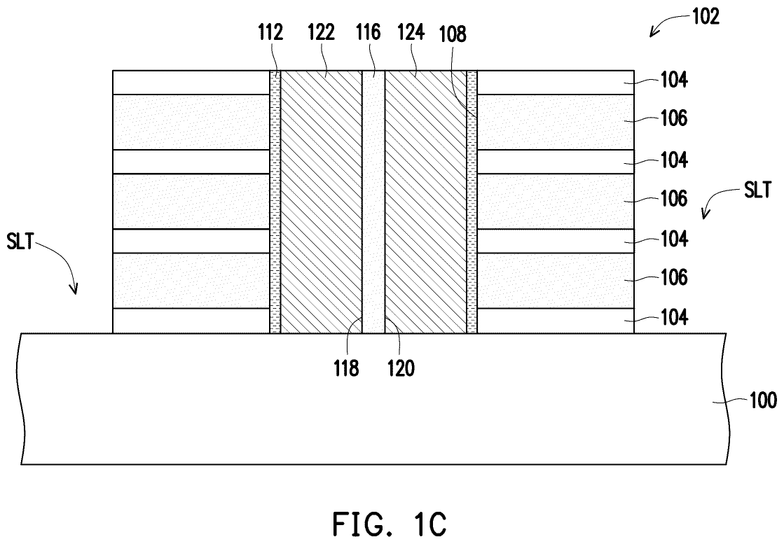

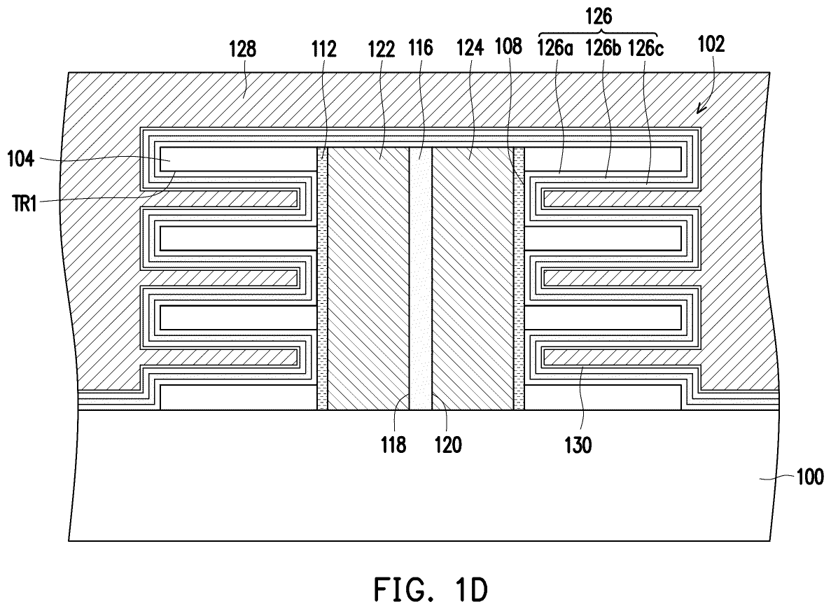

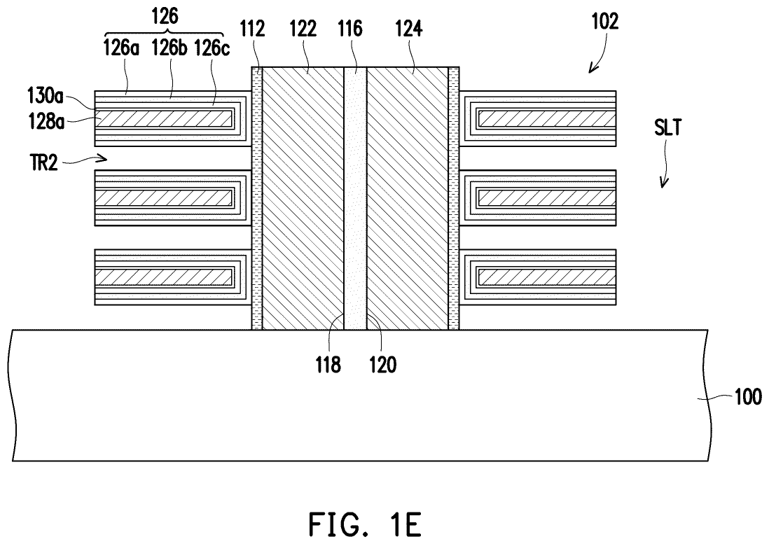

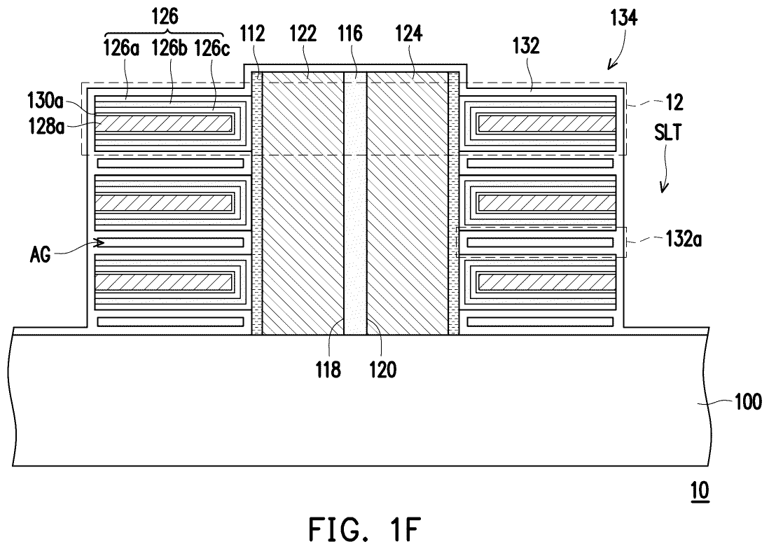

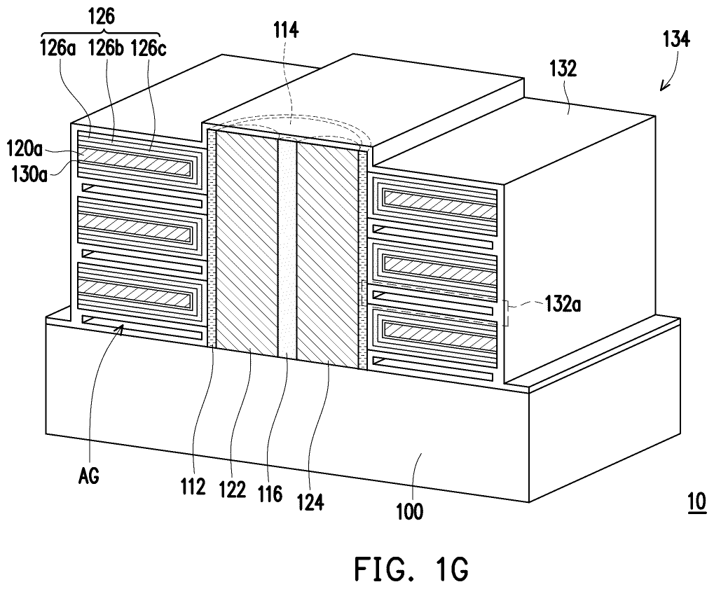

FIGS. 1A to 1F are schematic cross-sectional views of a manufacturing process of a three-dimensional flash memory according to the first embodiment of the disclosure.

First, referring to FIG. 1A, an initial stacked structure 102 is formed on a dielectric substrate 100. The dielectric substrate 100 is, for example, a dielectric layer formed on a silicon substrate, which is, for example, a silicon oxide layer. The initial stacked structure 102 is formed by an insulation material layer 104 and a sacrificial layer 106 alternately stacked on the dielectric substrate 100. In this embodiment, a lowermost layer and an uppermost layer of the initial stacked structure 102 are the insulation material layers 104. The insulation material layer 104 is, for example, a relatively low-density silicon oxide layer. The sacrificial layer 106 is, for example, a silicon nitride layer. In this embodiment, the initial stacked structure 102 has four insulation material layers 104 and three sacrificial layers 106, but the disclosure is not limited thereto. In other embodiments, more insulation material layers 104 and more sacrificial layers 106 may be formed according to actual requirements.

Next, a hole 108 is formed in the initial stacked structure 102. In this embodiment, the hole 108 exposes the dielectric substrate 100, but the disclosure is not limited thereto. In other embodiments, a bottom of the hole 108 may be located in the lowermost insulation material layer 104. That is, the hole 108 does not expose the dielectric substrate 100. In addition, in other embodiments, the bottom of the hole 108 may be located in the dielectric substrate 100. From a top view above the dielectric substrate 100, the hole 108 may have a circular or other shaped outline. The hole 108 is used to define a position of a vertical channel (VC) of the three-dimensional flash memory in this embodiment.

Then, referring to FIG. 1B, a channel layer 112 is formed on an inner surface of the hole 108. The channel layer 112 is, for example, an undoped polysilicon layer. A method of forming the channel layer 112 is, for example, to conformally form a channel material layer on a top surface of the uppermost insulation material layer 104 and the inner surface and the bottom of the hole 108, and then perform an anisotropic etching process, so as to remove the channel material layer on the top surface of the insulation material layer 104 and the bottom of the hole 108. Since the channel layer 112 is formed on the inner surface of the hole 108, the channel layer 112 may be regarded as an annular channel pillar, and the channel layer 112 is continuous in an extension direction thereof (between a top and the bottom of the hole 108). “The channel layer 112 is continuous in an extension direction thereof” means that the channel layer 112 is integral in the extension direction thereof, and is not divided into a plurality of disconnected portions.

Afterwards, an insulation layer 114 is formed in the hole 108. The insulation layer 114 is, for example, a silicon oxide layer. In this embodiment, the insulation layer 114 does not fill the hole 108 but retains a central portion of the hole 108 and exposes the dielectric substrate 100. Then, an insulation layer 116 is formed in the hole 108 to fill the central portion of the hole 108. The insulation layer 116 may be regarded as an insulation pillar. The insulation layer 116 is, for example, a silicon nitride layer. In other embodiments, the hole 108 may be filled with the insulation layer 114 first, and then a hole exposing the dielectric substrate 100 is formed in the insulation layer 114 and filled with the insulation layer 116.

Next, referring to FIG. 1C, a hole 118 and a hole 120 are formed in the insulation layer 114. The hole 118 and the hole 120 expose the dielectric substrate 100. From the top view above the dielectric substrate 100, the hole 118 and the hole 120 may have circular or other shaped outlines. The hole 118 and the hole 120 are respectively formed on two opposite sides of the insulation layer 116, and are in contact with the channel layer 112. The hole 118 and the hole 120 are used to define positions of a source/drain of the three-dimensional flash memory in this embodiment.

Then, a doped polysilicon layer is formed in the hole 118 and the hole 120 to form a source/drain pillar 122 and a source/drain pillar 124 of the three-dimensional flash memory in this embodiment. In this way, the source/drain pillar 122 and the source/drain pillar 124 may be located inside the annular channel pillar (the channel layer 112), and separated from each other by the insulation pillar (the insulation layer 116) and connected to the channel pillar (the channel layer 112).

Afterwards, a portion of the initial stacked structure 102 is removed to form a slit SLT exposing the dielectric substrate 100.

Then, referring to FIG. 1D, the sacrificial layer 106 in the initial stacked structure 102 is removed to form a trench TR1 between the adjacent insulation material layers 104. A method of removing the sacrificial layer 106 is well known to those skilled in the art and will not be further described here. Next, a charge storage structure 126 is conformally formed on the initial stacked structure 102. The charge storage structure 126 is filled in the trench TR1 and formed on a sidewall and a bottom of the trench TR1. The charge storage structure 126 may be formed by a silicon oxide layer 126a, a silicon nitride layer 126b, and a silicon oxide layer 126c stacked in sequence. In this embodiment, compared to the insulation material layer 104, the silicon oxide layer 126a and the silicon oxide layer 126c are relatively high-density silicon oxide layers.

After the charge storage structure 126 is formed, a gate material layer 128 is formed on the dielectric substrate 100, and the gate material layer 128 is filled in the trench TR1. In this embodiment, the gate material layer 128 may be a metal layer. Therefore, before the gate material layer 128 is formed, a high dielectric constant material layer 130 may be formed on the charge storage structure 126. The high dielectric constant material generally refers to a dielectric material with a dielectric constant greater than 4 in this technical field. A material of the high dielectric constant material layer 130 may be aluminum oxide (Al₂O₃), tantalum oxide (Ta₂O₃), titanium oxide (TiO₂), yttrium oxide (Y₂O₃), zirconium oxide (ZrO₂), hafnium oxide (HfO₂), or lanthanum oxide (La₂O₃). In other embodiments, the high dielectric constant material layer 130 may be omitted.

Next, referring to FIG. 1E, the anisotropic etching process may be performed to remove the charge storage structure 126, the gate material layer 128, and the high dielectric constant material layer 130 outside the trench TR1. In this way, a gate layer 128a formed by the gate material layer 128, a high dielectric constant layer 130a formed by the high dielectric constant material layer 130, and the charge storage structure 126 are formed in the trench TR1.

Then, the insulation material layer 104 is removed to form a trench TR2. A method of removing the insulation material layer 104 is, for example, to perform a wet etching process, so that an etchant passes through slit SLT to remove the insulation material layer 104. In this embodiment, since the insulation material layer 104 is the relatively low-density silicon oxide layer, and the silicon oxide layer 126a and the silicon oxide layer 126c are relatively the high-density silicon oxide layers, only the insulation material layer 104 is removed during the wet etching process.

Afterwards, referring to FIG. 1F, an insulation material layer 132 is conformally formed on a surface of the initial stacked structure 102. The insulation material layer 132 is filled in the trench TR2 and formed on a sidewall and a bottom of the trench TR2. In addition, by controlling a thickness of the insulation material layer 132, an end portion of the trench TR2 may be sealed by the insulation material layer 132 to form an air gap AG in the trench TR2. Therefore, an insulation layer 132a formed by the insulation material layer 132 is formed between the adjacent gate layers 128a, and the insulation layer 132a has the air gap AG. The gate layer 128a and the insulation layer 132a alternately stacked on the dielectric substrate 100 form a stacked structure 134. The air gap AG extends in an extension direction of the gate layer 128a, and a width of the air gap AG in the extension direction is greater than a thickness of the air gap AG in a stacking direction of the stacked structure 134. In this way, a three-dimensional flash memory 10 in this embodiment is formed. A schematic perspective view of the three-dimensional flash memory 10 is shown in FIG. 1G.

In the three-dimensional flash memory 10 of this embodiment, the stacked structure 134 formed by the gate layer 128a and the insulation layer 132a is disposed on the dielectric substrate 100, and the insulation layer 132a has the air gap AG. The channel pillar (the channel layer 112) is disposed on the dielectric substrate 100 and penetrates through the stacked structure 134. The source/drain pillar 122 and the source/drain pillar 124 are disposed on the dielectric substrate 100, located inside the channel pillar, and penetrates through the stacked structure 134. The charge storage structure 126 is disposed between the gate layer 128a and the channel pillar. In addition, in the channel pillar, the source/drain pillar 122 and the source/drain pillar 124 are respectively connected to the channel pillar and separated from each other by the insulation column 116.

In addition, the three-dimensional flash memory 10 has a plurality of memory units 12. As shown in FIG. 1F, in the three-dimensional flash memory 10, there are three memory units 12 stacked on each other. Depending on the actual requirements, a plurality of three-dimensional flash memories 10 may be arranged on the dielectric substrate 100 in an array, which is well known to those skilled in the art and will not be further described here.

In the three-dimensional flash memory 10, in the stacking direction of the stacked structure 134, the insulation layer 132a having the air gap AG is located between the adjacent gate layers 128a. Since the air in the air gap AG has a relatively low dielectric constant (approximately equal to 1), there may be a low capacitance value between the adjacent gate layers 128a. Therefore, a RC delay of the three-dimensional flash memory 10 during an operation process may be effectively reduced, thereby improving operation efficiency of the three-dimensional flash memory 10. In addition, the air gap AG in the insulation layer 132a may effectively avoid increased interference between the adjacent memory units 12.

By performing an incremental step pulse program (ISPP) simulation test on the three-dimensional flash memory 10, it may be found that when the same voltage is applied, compared to a case where there is no hole in the insulation layer between the adjacent gate layers, a slope in a diagram showing a relationship between a programming voltage and a threshold voltage (VT) obtained by testing the three-dimensional flash memory 10 may be increased, indicating that the three-dimensional flash memory 10 may have better operation efficiency.

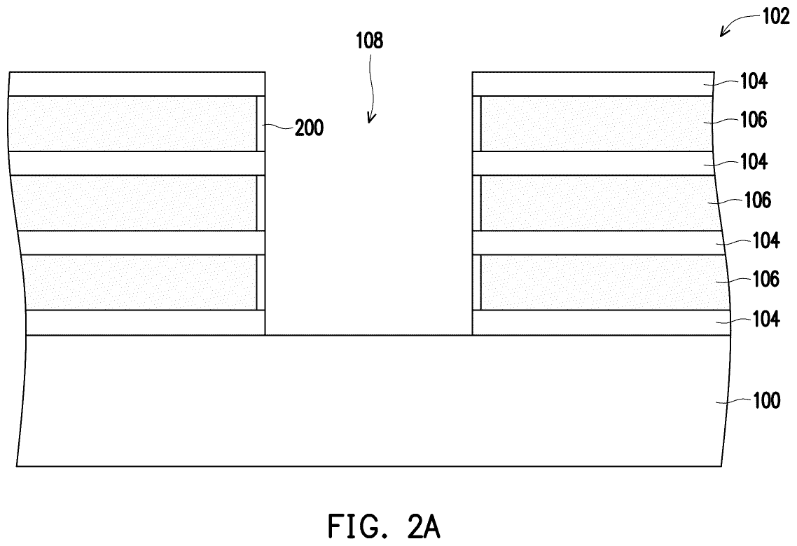

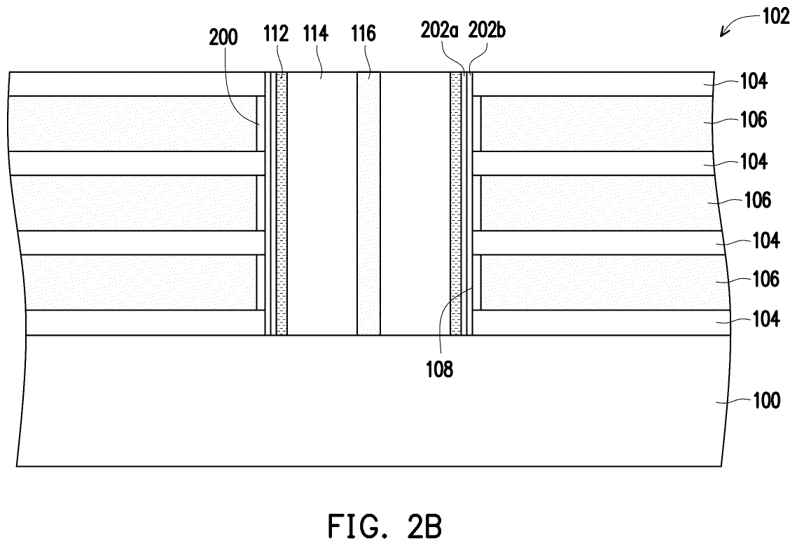

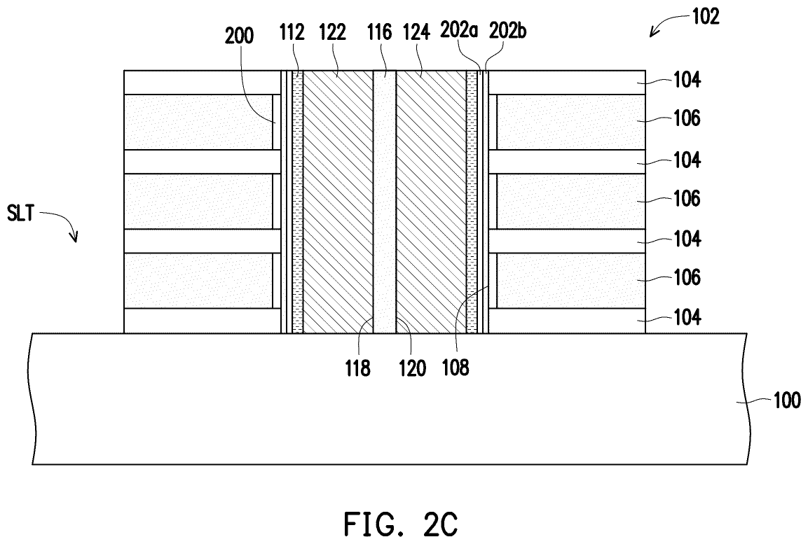

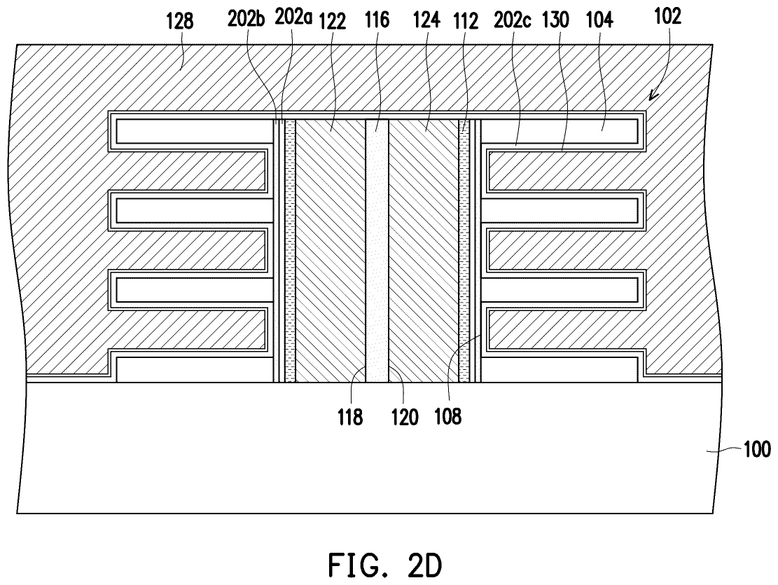

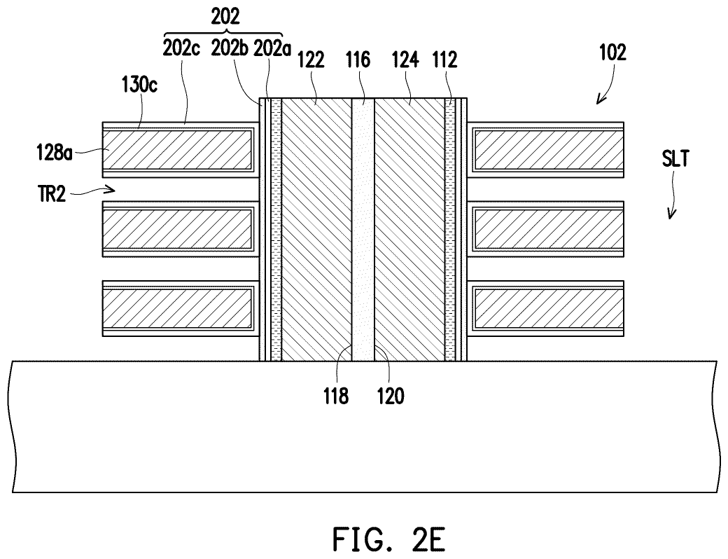

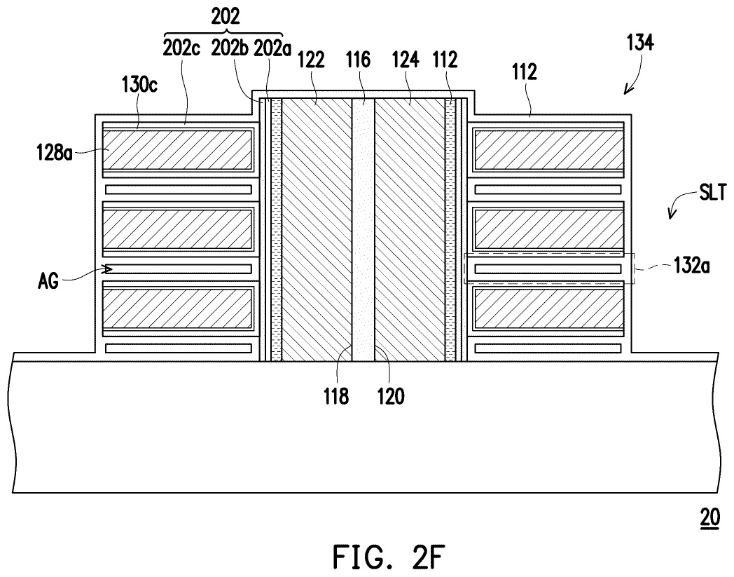

FIGS. 2A to 2F are schematic cross-sectional views of a manufacturing process of a three-dimensional flash memory according to the second embodiment of the disclosure. In this embodiment, the same elements as those in the first embodiment will be denoted by the same reference numerals, and will not be described again.

First, referring to FIG. 2A, after the initial stacked structure 102 in FIG. 1A is formed, a sacrificial silicon oxide layer 200 is formed on a surface of the sacrificial layer 106 exposed by the hole 108 as a channel hole. A method of forming the sacrificial silicon oxide layer 200 is, for example, to perform an oxidation process on the sacrificial layer 106 exposed in the hole 108, so that a portion of the sacrificial layer 106 is oxidized into the sacrificial silicon oxide layer 200.

Next, referring to FIG. 2B, a silicon nitride layer 202b, a silicon oxide layer 202a, and the channel pillar (the channel layer 112) are formed on a sidewall of the hole 108 in sequence. Compared to the insulation material layer 104, the silicon oxide layer 202a is a relatively high-density silicon oxide layer. Afterwards, similar to the steps described in FIG. 1B, the insulation layer 114 and the insulation layer 116 are formed in the hole 108.

Then, referring to FIG. 2C, similar to the steps described in FIG. 1C, the source/drain pillar 122 and the source/drain pillar 124 are formed in the insulation layer 114, and the slit SLT exposing the dielectric substrate 100 is formed.

Next, referring to FIG. 2D, similar to the steps described in FIG. 1D, the sacrificial layer 106 in the initial stacked structure 102 is removed. During a process of removing the sacrificial layer 106, damage to the silicon nitride layer 202b may be avoided due to existence of the sacrificial silicon oxide layer 200. After the sacrificial layer 106 is removed, the sacrificial silicon oxide layer 200 is removed. Then, a silicon oxide layer 202c is conformally formed on the initial stacked structure 102. Compared to the insulation material layer 104, the silicon oxide layer 202c is a relatively high-density silicon oxide layer. Afterwards, similar to the steps described in FIG. 1D, the gate material layer 128 and the high dielectric constant material layer 130 are formed.

Then, referring to FIG. 2E, similar to the steps described in FIG. 1E, the anisotropic etching process may be performed to form the gate layer 128a and the high dielectric constant layer 130a. In addition, the silicon oxide layer 202a, the silicon nitride layer 202b, and the silicon oxide layer 202c between the gate layer 128a and the channel layer 112 form a charge storage structure 202. Then, through the slit SLT, the wet etching process is performed to remove the insulation material layer 104 to form the trench TR2. Since the insulation material layer 104 is the relatively low-density silicon oxide layer, and the silicon oxide layer 202a and the silicon oxide layer 202c are relatively high-density silicon oxide layers, only the insulation material layer 104 is removed during the wet etching process.

Afterwards, referring to FIG. 2F, similar to the steps described in FIG. 1F, the insulation material layer 132 is conformally formed on the surface of the initial stacked structure 102. Therefore, the insulation layer 132a formed by the insulation material layer 132 is formed between the adjacent gate layers 128a, and the insulation layer 132a has the air gap AG. The gate layer 128a and the insulation layer 132a alternately stacked on the dielectric substrate 100 form the stacked structure 134. In this way, a three-dimensional flash memory 20 in this embodiment is formed.

In the three-dimensional flash memory 20, the silicon nitride layer 202b in the charge storage structure 202 is continuous in the stacking direction of the stacked structure 134, so that the insulation layer 132a is in contact with the silicon nitride layer 202b.

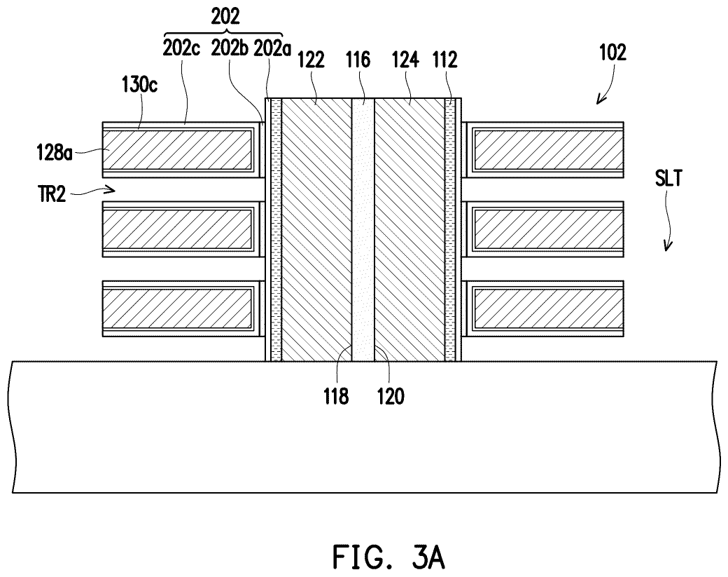

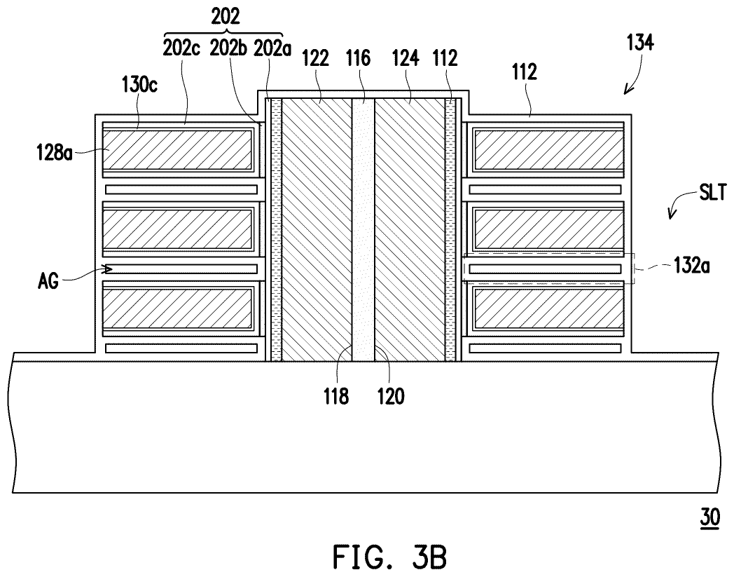

FIGS. 3A to 3B are schematic cross-sectional views of a manufacturing process of a three-dimensional flash memory according to the third embodiment of the disclosure. In this embodiment, the same elements as those in the second embodiment will be denoted by the same reference numerals, and will not be described again.

First, referring to FIG. 3A, in the steps as described in FIG. 2E, after the insulation material layer 104 is removed through the slit SLT, the exposed silicon nitride layer 202b is further removed to expose the silicon oxide layer 202a. In this way, the silicon nitride layer 202b is only located between the gate layer 128a and the channel layer 112.

Afterwards, referring to FIG. 3B, similar to the steps described in FIG. 2F, the insulation material layer 132 is conformally formed on the surface of the initial stacked structure 102. Therefore, the insulation layer 132a formed by the insulation material layer 132 is formed between the adjacent gate layers 128a, and the insulation layer 132a has the air gap AG. The gate layer 128a and the insulation layer 132a alternately stacked on the dielectric substrate 100 form the stacked structure 134. In this way, a three-dimensional flash memory 30 in this embodiment is formed.

In the three-dimensional flash memory 30, the silicon nitride layer 202b in the charge storage structure 202 is discontinuous in the stacking direction of the stacked structure 134, so that the insulation layer 132a is in contact with the silicon oxide layer 202a. Since the silicon nitride layer 202b is discontinuous in the stacking direction of the stacked structure 134, a formed electric field may be more concentrated during the operation process, so that electrons may be stored more densely in the charge storage structure 202 between the gate layer 128a and the channel layer 112 to prevent the electrons from moving and causing a change in the threshold voltage.

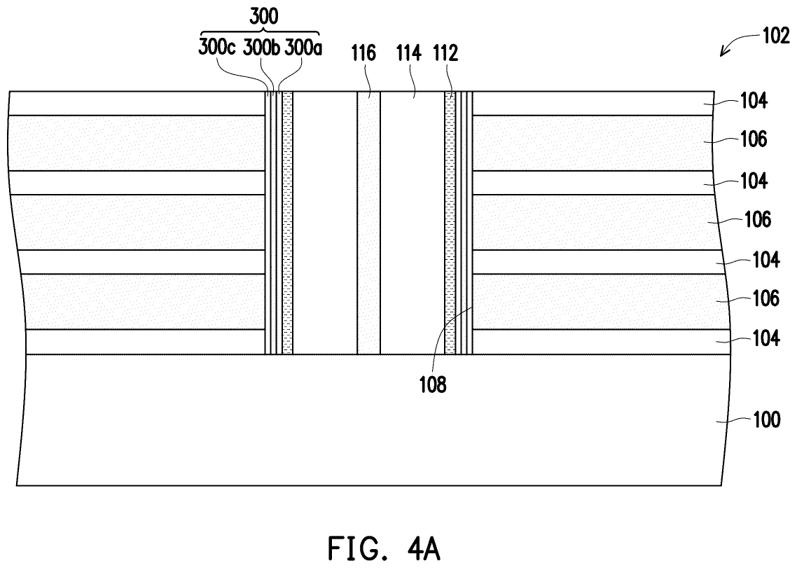

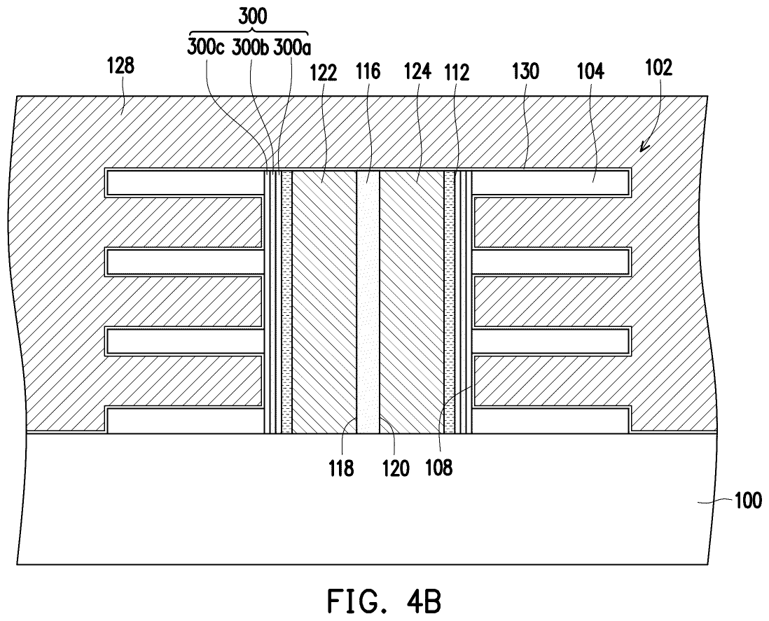

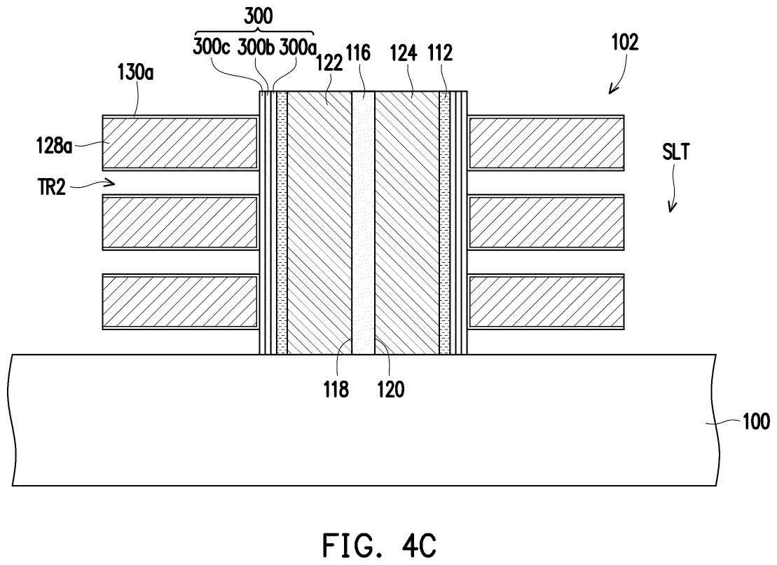

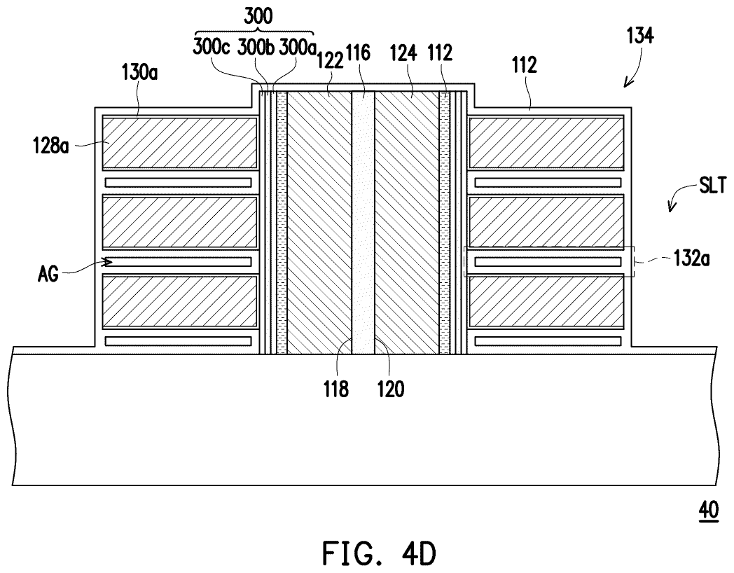

FIGS. 4A to 4D are schematic cross-sectional views of a manufacturing process of a three-dimensional flash memory according to the fourth embodiment of the disclosure. In this embodiment, the same elements as those in the first embodiment will be denoted by the same reference numerals, and will not be described again.

First, referring to FIG. 4A, after the initial stacked structure 102 in FIG. 1A is formed, a silicon oxide layer 300c, a silicon nitride layer 300b, a silicon oxide layer 300a, and the channel pillar (the channel layer 112) are formed on the sidewall of the hole 108 as the channel hole in sequence. Compared to the insulation material layer 104, the silicon oxide layer 300c and the silicon oxide layer 300a are relatively high-density silicon oxide layers. The silicon oxide layer 300a, the silicon nitride layer 300b, and the silicon oxide layer 300c form a charge storage structure 300. Afterwards, similar to the steps described in FIG. 1B, the insulation layer 114 and the insulation layer 116 are formed in the hole 108.

Next, referring to FIG. 4B, similar to the steps described in FIGS. 1C and 1D, the source/drain pillar 122 and the source/drain pillar 124 are formed in the insulation layer 114, and the slit SLT exposing the dielectric substrate 100 is formed. The sacrificial layer 106 in the initial stacked structure 102 is removed. The high dielectric constant material layer 130 and the gate material layer 128 are formed.

Then, referring to FIG. 4C, similar to the steps described in FIG. 1E, the anisotropic etching process may be performed to form the gate layer 128a and the high dielectric constant layer 130a. Then, through the slit SLT, the wet etching process is performed to remove the insulation material layer 104 to form the trench TR2. Since the insulation material layer 104 is the relatively low-density silicon oxide layer, and the silicon oxide layer 300a and the silicon oxide layer 300c are relatively high-density silicon oxide layers, only the insulation material layer 104 is removed during the wet etching process.

Afterwards, referring to FIG. 4D, similar to the steps described in FIG. 1F, the insulation material layer 132 is conformally formed on the surface of the initial stacked structure 102. Therefore, the insulation layer 132a formed by the insulation material layer 132 is formed between the adjacent gate layers 128a, and the insulation layer 132a has the air gap AG. The gate layer 128a and the insulation layer 132a alternately stacked on the dielectric substrate 100 form the stacked structure 134. In this way, a three-dimensional flash memory 40 in this embodiment is formed.

In the three-dimensional flash memory 40, the silicon oxide layer 300c and the silicon nitride layer 300b in the charge storage structure 300 are continuous in the stacking direction of the stacked structure 134, so that the insulation layer 132a is in contact with the silicon oxide layer 300c.

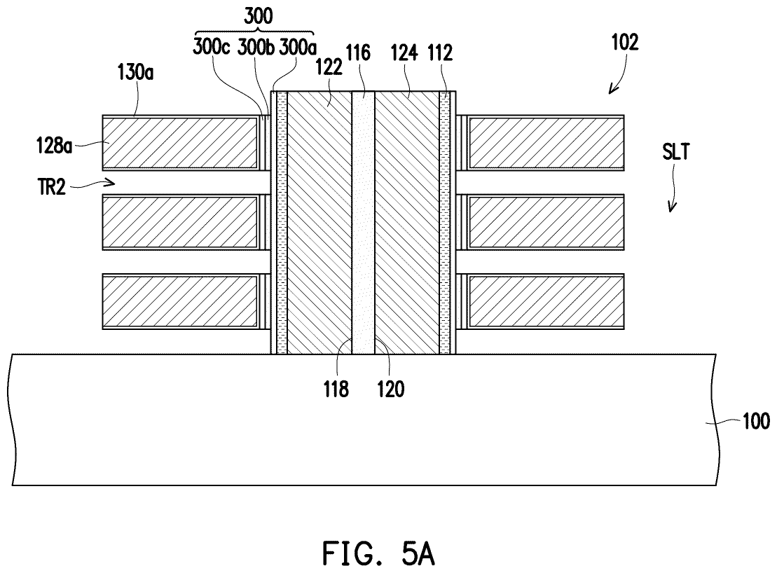

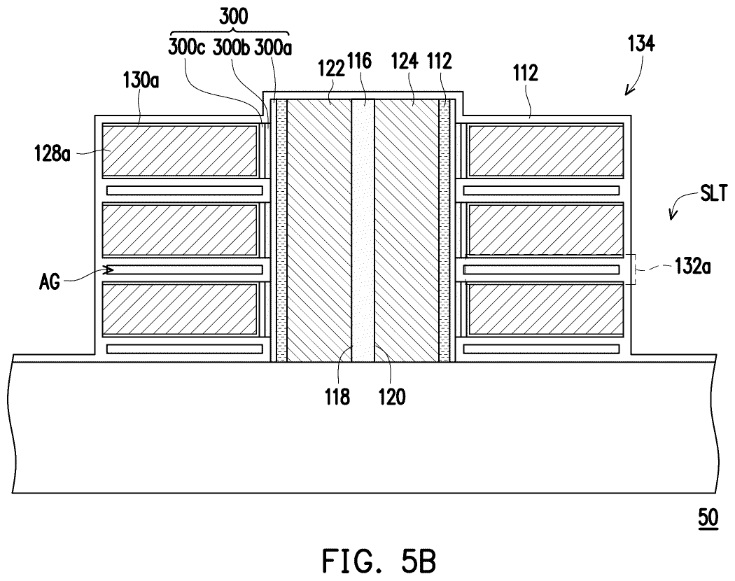

FIGS. 5A to 5B are schematic cross-sectional views of a manufacturing process of a three-dimensional flash memory according to the fifth embodiment of the disclosure. In this embodiment, the same elements as those in the fourth embodiment will be denoted by the same reference numerals, and will not be described again.

First, referring to FIG. 5A, in the steps as described in FIG. 4C, after the insulation material layer 104 is removed through the slit SLT, the exposed silicon oxide layer 300c is further removed to expose the silicon nitride layer 300b. After the exposed silicon oxide layer 300c is removed, the exposed silicon nitride layer 300b is further removed to expose the silicon oxide layer 300a. In this way, the silicon nitride layer 300b is only located between the gate layer 128a and the channel layer 112.

Afterwards, referring to FIG. 5B, similar to the steps described in FIG. 4D, the insulation material layer 132 is conformally formed on the surface of the initial stacked structure 102. Therefore, the insulation layer 132a formed by the insulation material layer 132 is formed between the adjacent gate layers 128a, and the insulation layer 132a has the air gap AG. The gate layer 128a and the insulation layer 132a alternately stacked on the dielectric substrate 100 form the stacked structure 134. In this way, a three-dimensional flash memory 50 in this embodiment is formed.

In the three-dimensional flash memory 50, the silicon nitride layer 300b in the charge storage structure 300 is discontinuous in the stacking direction of the stacked structure 134, so that the insulation layer 132a is in contact with the silicon oxide layer 300a. Since the silicon nitride layer 300b is discontinuous in the stacking direction of the stacked structure 134, the formed electric field may be more concentrated during the operation process, so that the electrons may be stored more densely in the charge storage structure 300 between the gate layer 128a and the channel layer 112 to prevent the electrons from moving and causing the change in the threshold voltage.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A three-dimensional flash memory, comprising:
a stacked structure, disposed on a dielectric substrate and comprising a plurality of gate layers and a plurality of insulation layers alternately stacked, wherein each of the insulation layers has an air gap;
an annular channel pillar, disposed on the dielectric substrate and penetrating through the stacked structure;
a first source/drain pillar and a second source/drain pillar, disposed on the dielectric substrate, located inside the channel pillar, and penetrating through the stacked structure, wherein the first source/drain pillar and the second source/drain pillar are separated from each other, and each is connected to the channel pillar; and
a charge storage structure, disposed between each of the gate layers and the channel pillar.

2. The three-dimensional flash memory according to claim 1, wherein the air gap extends in an extension direction of the gate layer.

3. The three-dimensional flash memory according to claim 2, wherein a width of the air gap in the extension direction is greater than a thickness of the air gap in a stacking direction of the stacked structure.

4. The three-dimensional flash memory according to claim 1, wherein the charge storage structure comprises a first silicon oxide layer, a second silicon oxide layer, and a silicon nitride layer located between the first silicon oxide layer and the second silicon oxide layer, and the first silicon oxide layer is in contact with the channel pillar.

5. The three-dimensional flash memory according to claim 4, wherein the insulation layer is in contact with the channel pillar, and the charge storage structure is located between the gate layer and the channel pillar and between the gate layer and the insulation layer.

6. The three-dimensional flash memory according to claim 4, wherein the first silicon oxide layer and the silicon nitride layer are located between the stacked structure and the channel pillar, and the second silicon oxide layer is located between the gate layer and the silicon nitride layer and between the gate layer and the insulation layer.

7. The three-dimensional flash memory according to claim 6, wherein the silicon nitride layer is continuous in a stacking direction of the stacked structure, so that the insulation layer is in contact with the silicon nitride layer.

8. The three-dimensional flash memory according to claim 6, wherein the silicon nitride layer is discontinuous in a stacking direction of the stacked structure, so that the insulation layer is in contact with the first silicon oxide layer.

9. The three-dimensional flash memory according to claim 4, wherein the charge storage structure is located between the channel pillar and the stacked structure, and the second silicon oxide layer is continuous in a stacking direction of the stacked structure, so that the insulation layer is in contact with the second silicon oxide layer.

10. The three-dimensional flash memory according to claim 4, wherein the charge storage structure is located between the channel pillar and the stacked structure, and the silicon nitride layer and the second silicon oxide layer are discontinuous in a stacking direction of the stacked structure, so that the insulation layer is in contact with the first silicon oxide layer.

11. The three-dimensional flash memory according to claim 1, wherein the gate layer comprises a metal layer, and the three-dimensional flash memory further comprises a high dielectric constant layer disposed between the gate layer and the charge storage structure.

12. The three-dimensional flash memory according to claim 1, further comprising an insulation pillar disposed between the first source/drain pillar and the second source/drain pillar.

13. A manufacturing method of a three-dimensional flash memory, comprising:
forming a stacked structure on a dielectric substrate, wherein the stacked structure comprises a plurality of gate layers and a plurality of insulation layers alternately stacked, and each of the insulation layers has an air gap;
forming an annular channel pillar on the dielectric substrate, wherein the channel pillar penetrates through the stacked structure;
forming a first source/drain pillar and a second source/drain pillar on the dielectric substrate, wherein the first source/drain pillar and the second source/drain pillar are located inside the channel pillar and penetrate through the stacked structure, and the first source/drain pillar and the second source/drain pillar are separated from each other, and each is connected to the channel pillar; and
forming a charge storage structure between each of the gate layers and the channel pillar.

14. The manufacturing method of the three-dimensional flash memory according to claim 13, wherein the air gap extends in an extension direction of the gate layer.

15. The manufacturing method of the three-dimensional flash memory according to claim 14, wherein a width of the air gap in the extension direction is greater than a thickness of the air gap in a stacking direction of the stacked structure.

16. The manufacturing method of the three-dimensional flash memory according to claim 13, wherein the charge storage structure comprises a first silicon oxide layer, a second silicon oxide layer, and a silicon nitride layer located between the first silicon oxide layer and the second silicon oxide layer, and the first silicon oxide layer is in contact with the channel pillar.

17. The manufacturing method of the three-dimensional flash memory according to claim 16, wherein a method of forming the stacked structure and the charge storage structure comprises:
forming an initial stacked structure on the dielectric substrate, wherein the initial stacked structure comprises a plurality of first insulation material layers and a plurality of sacrificial layers alternately stacked;
forming the channel pillar, the first source/drain pillar, and the second source/drain pillar in the initial stacked structure;
removing the plurality of sacrificial layers to form a plurality of first trenches;
forming the charge storage structure on surfaces of the first trenches;
filling the gate layers in the first trenches;
removing the plurality of first insulation material layers to form a plurality of second trenches; and
conformally forming a second insulation material layer on a surface of the initial stacked structure, and sealing, by the second insulation material layer, end portions of the second trenches to form the insulation layers and the air gaps.

18. The manufacturing method of the three-dimensional flash memory according to claim 16, wherein a method of forming the stacked structure and the charge storage structure comprises:
forming an initial stacked structure on the dielectric substrate, wherein the initial stacked structure comprises a plurality of sacrificial layers and a plurality of first insulation material layers alternately stacked;
forming a channel hole in the initial stacked structure;
forming a sacrificial silicon oxide layer on surfaces of the sacrificial layers exposed by the channel hole;
forming the silicon nitride layer, the first silicon oxide layer, and the channel pillar in sequence on a sidewall of the channel hole;
forming the first source/drain pillar and the second source/drain pillar in the channel hole;
removing the plurality of sacrificial layers and the sacrificial silicon oxide layer to form a plurality of first trenches;
forming the second silicon oxide layer on surfaces of the first trenches;
filling the gate layers in the first trenches;
removing the plurality of first insulation material layers to form a plurality of second trenches; and
conformally forming a second insulation material layer on a surface of the initial stacked structure, and sealing, by the second insulation material layer, end portions of the second trenches to form the insulation layers and the air gaps.

19. The manufacturing method of the three-dimensional flash memory according to claim 18, further comprising removing the exposed silicon nitride layer to expose the first silicon oxide layer after the plurality of first insulation material layers are removed.

20. The manufacturing method of the three-dimensional flash memory according to claim 16, wherein a method of forming the stacked structure and the charge storage structure comprises:
forming an initial stacked structure on the dielectric substrate, wherein the initial stacked structure comprises a plurality of sacrificial layers and a plurality of first insulation material layers alternately stacked;
forming a channel hole in the initial stacked structure;
forming the charge storage structure and the channel pillar in sequence on a sidewall of the channel hole;
forming the first source/drain pillar and the second source/drain pillar in the channel hole;
removing the plurality of sacrificial layers to form a plurality of first trenches;
filling the gate layers in the first trenches;
removing the plurality of first insulation material layers to form a plurality of second trenches; and
conformally forming a second insulation material layer on a surface of the initial stacked structure, and sealing, by the second insulation material layer, end portions of the second trenches to form the insulation layers and the air gaps.

21. The manufacturing method of the three-dimensional flash memory according to claim 20, wherein after the first insulation material layers are removed, the manufacturing method further comprises:
removing the exposed first silicon oxide layer to expose the silicon nitride layer; and
removing the exposed silicon nitride layer to expose the first silicon oxide layer.

22. The manufacturing method of the three-dimensional flash memory according to claim 13, wherein the gate layer comprises a metal layer, and the manufacturing method further comprises forming a high dielectric constant layer between the gate layer and the charge storage structure.

23. The manufacturing method of the three-dimensional flash memory according to claim 13, further comprising forming an insulation pillar between the first source/drain pillar and the second source/drain pillar.
